(19) United States
(12) Patent Application Publication
(10) Pub. No.: US 2025/0311358 A1
(43) Pub. Date: Oct. 2, 2025

(54) INNER SPACER INCLUDING SEMICONDUCTOR OXIDATION FOR RULE SCALING AND INCREASED STRAIN

(71) Applicant: Taiwan Semiconductor Manufacturing Company, Ltd., Hsinchu (TW)

(72) Inventors: Jung-Chien CHENG, Hsinchu (TW); Guan-Lin CHEN, Hsinchu (TW); Shi Ning JU, Hsinchu (TW); Kuo-Cheng CHIANG, Hsinchu (TW); Chih-Hao WANG, Hsinchu (TW); Chia-Hao YU, Hsinchu (TW)

(21) Appl. No.: 18/807,674

(22) Filed: Aug. 16, 2024

Related U.S. Application Data
(60) Provisional application No. 63/571,371, filed on Mar. 28, 2024.

(51) Int. Cl. H01L 29/66; H01L 29/06; H01L 29/423; H01L 29/775; H01L 29/786

(52) U.S. Cl. CPC H10D 64/018; H10D 30/014; H10D 30/43; H10D 30/6735; H10D 30/6757; H10D 62/121

(57) ABSTRACT

A method of forming a transistor includes forming a plurality of stacked channel of the transistor, forming a plurality of semiconductor structures interleaved with the channels, and forming a semiconductor seed layer in a source/drain trench on ends of the channels and the semiconductor structures. A source/drain region of the transistor is then grown epitaxially from the seed layer in the source/drain trench. The semiconductor structures are then replaced with dielectric inner spacers. A gate metal is then formed wrapped around the channels and separated from the source/drain region by the dielectric inner spacers.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1-19B are perspective and cross-sectional views of an integrated circuit at various stages of processing, in accordance with some embodiments.

FIGS. 20A-22B are perspective and cross-sectional views of an integrated circuit at various stages of processing, in accordance with some embodiments.

FIG. 23 is a cross-sectional view of an integrated circuit, in accordance with some embodiments.

FIG. 24 is a cross-sectional view of an integrated circuit, in accordance with some embodiments.

FIG. 25 is a flow diagram of a method for forming an integrated circuit, in accordance with some embodiments.

FIG. 26 is a flow diagram of a method for forming an integrated circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The present disclosure is generally related to semiconductor devices, and more particularly to field-effect transistors (FETs), such as planar FETs, three-dimensional fin FETs (FinFETs), or nanostructure devices. Examples of nanostructure devices include gate-all-around (GAA) devices, nanosheet FETs (NSFETs), nanowire FETs (NWFETs), and the like. In advanced technology nodes, active area spacing between nanostructure devices is generally uniform, source/drain epitaxy structures are symmetrical, and a metal gate surrounds four sides of the nanostructures (e.g., nanosheets). Gate-drain capacitance (“Cgd”) is increased due to larger metal gate endcap and increased source/drain epitaxy size.

Embodiments of the disclosure provide a gate all around transistor including first and second source/drain regions, a plurality of stacked channels each extending between the first and second source/drain regions, a gate metal wrapped around the channels, and low K inner spacers positioned between adjacent channels and electrically isolating the gate metal from the source/drain regions. Embodiments of the present disclosure advantageously form the inner spacers after formation of the source/drain regions. More particularly, embodiments of the present disclosure form dielectric nanostructures between the channels, recess the dielectric nanostructures, form semiconductor structures in the recesses, and form a semiconductor seed layer on the ends of the channels and on the outside surfaces of the semiconductor structures. The source/drain regions are grown epitaxially from the semiconductor seed layer and the dielectric nanostructures are removed. After removal of the dielectric nanostructures, low K dielectric inner spacers are formed in place of the sacrificial semiconductor nanostructures. The dielectric inner spacers can include an oxide or an air gap. The gate metal is then formed. The result is reduced capacitance between the gate metal and source/drain regions, increased switching speeds of the transistor, higher-quality source/drain regions, enhanced strain for improved device performance, and reduced time in forming the source/drain regions.

The transistors may be termed “nanostructure transistors” and the channels may be termed “semiconductor nanostructures”. The nanostructure transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure transistor structure.

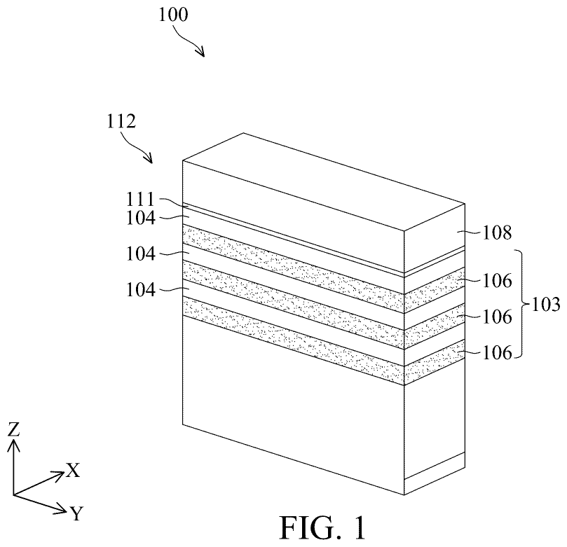

FIGS. 1-19B are perspective and side-sectional views of a portion of an integrated circuit 100 at various stages of processing, in accordance with some embodiments. The fabrication process results in a plurality of transistors 101, as will be described in further detail below.

FIG. 1 is a perspective view of the integrated circuit 100 at an intermediate state of processing, in accordance with some embodiments. The integrated circuit 100 includes a substrate 102. The substrate 102 may be a semiconductor substrate, such as a bulk semiconductor, or the like, which may be doped (e.g., with a p-type or an n-type dopant) or undoped. In an exemplary embodiment, the substrate includes silicon. Alternatively, the substrate 102 can include other semiconductor materials such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

The integrated circuit 100 includes a semiconductor stack 103 including a plurality of semiconductor layers 104 and sacrificial semiconductor layers 106 alternating with each other. As will be set forth in further detail below, the semiconductor layers 104 will be patterned to form stacked channels of a plurality of transistors. As set forth in more detail below, the sacrificial semiconductor layers 106 will eventually be entirely removed and are utilized to enable forming gate metals and other structures around the channels. In FIG. 1, three semiconductor layers 104 and three sacrificial semiconductor layers 106 are illustrated. In some embodiments, the multi-layer stack 103 may include fewer or more layers than are shown in FIG. 1.

In some embodiments, the semiconductor layers 104 may be formed of a first semiconductor material suitable for n-type semiconductor nanostructure transistors, such as silicon, silicon carbide, or the like, and the sacrificial semiconductor layers 106 may be formed of a second semiconductor material suitable for p-type semiconductor nanostructure transistors, such as silicon germanium or the like. Each of the layers of the multi-layer stack 103 may be epitaxially grown using a process such as vapor phase epitaxy (VPE), molecular beam epitaxy (MBE), chemical vapor deposition (CVD), atomic layer deposition (ALD), or the like.

As shown in FIG. 1, the integrated circuit 100 includes a hard mask layer 108 formed over the top sacrificial semiconductor layer 106. A thin dielectric layer 111 is positioned on the stack 103 below the hard mask layer 108. In some embodiments, the hard mask layer 108 includes a dielectric material. The dielectric material can include SiN, SiCN, SiOCN, SiOC, or other suitable dielectric materials. The hard mask layer 108 can have a thickness between 3 nm and 20 nm. In some embodiments, the dielectric layer 111 includes SiO, SiN, SiCN, SiOCN, SiOC, or other suitable dielectric materials. The dielectric layer 111 can have a thickness between 1 nm and 10 nm. Other materials and thicknesses may be utilized for the hard mask layer 108 and the dielectric layer 111 without departing from the scope of the present disclosure.

Due to high etch selectivity between the materials of the semiconductor layers 104 and the sacrificial semiconductor layers 106, the sacrificial semiconductor layers 106 of the second semiconductor material may be removed without significantly removing the semiconductor layers 104 of the first semiconductor material, thereby allowing the semiconductor layers 104 to be released to form stacked channel regions of transistors.

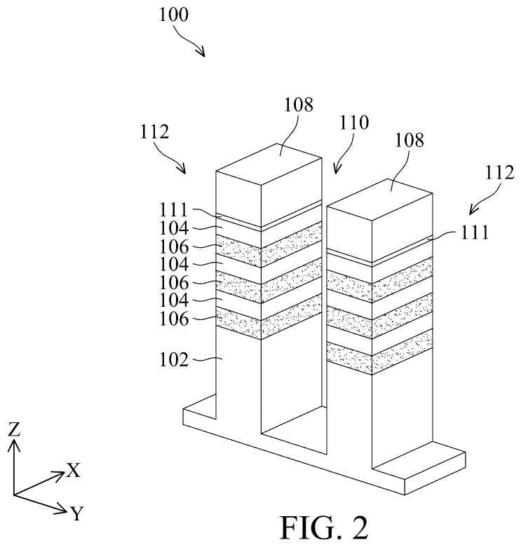

In FIG. 2, the hard mask layer 108 has been patterned in accordance with a photolithography process. After patterning of the hard mask layer 108, trenches 110 have been formed in the stack 103 and in the substrate 102. The trenches 110 can be formed with an anisotropic etching process that etches in the downward direction. The etching process defines semiconductor fins 112 by forming trenches 110 through the hard mask layer 108, the dielectric layer 111, the sacrificial semiconductor layers 106, the semiconductor layers 104, and the substrate 102. The result of the etching process is that a plurality of semiconductor fins 112 are formed from the stack 103. The semiconductor fins 112 extend in the X direction.

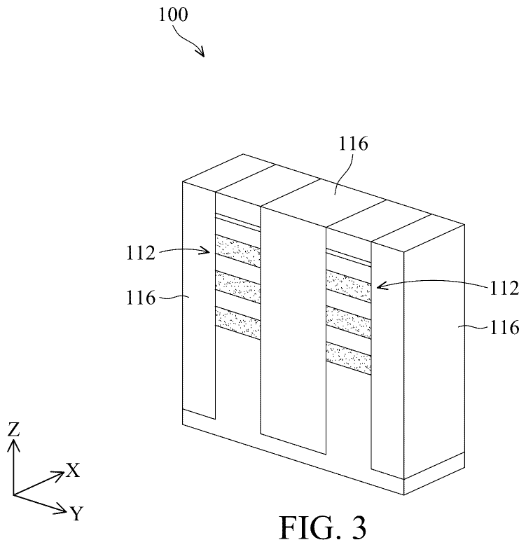

In FIG. 3, shallow trench isolation regions 116 have been formed by depositing a dielectric material in the trenches 110 between fins 112. The shell dielectric layer may be deposited by chemical vapor deposition (CVD), atomic layer deposition (ALD), physical vapor deposition (PVD), or other suitable deposition processes. In an exemplary embodiment, the dielectric material includes silicon oxide. However, the dielectric material can include SiN, SiCN, SiOC, SiOCN, or other dielectric materials without departing from the scope of the present disclosure. A chemical mechanical planarization (CMP) process has been performed to remove excess material of the shallow trench isolation region 116 from the top surface of the hard mask layer 108.

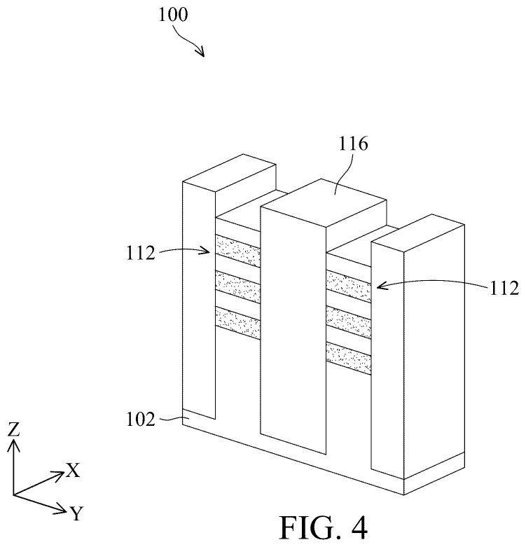

In FIG. 4, the hard mask layer 108 and the dielectric layer 110 the been removed. The result is that the top semiconductor layer 104 is exposed and has a top surface lower than the top surface of the shallow trench isolation region 116. The hard mask layer 108 and the dielectric layer 110 can be removed with one or more etching processes. The etching processes can include a wet etch, a dry etch, or other suitable etching processes.

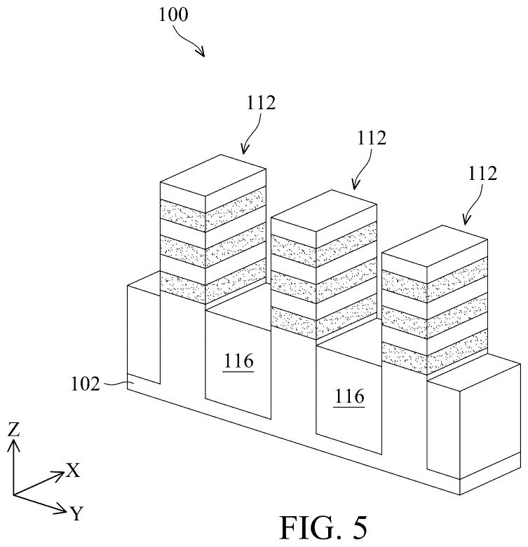

In FIG. 5, an etch-back process has been performed to recess the top of the shallow trench isolation regions 116, in accordance with some embodiments. The etchback process results in the completion of the shallow trench isolation regions 116. The top surface of the shallow trench isolation region 116 is lower than the lowest sacrificial semiconductor layer 106 of each stack 112.

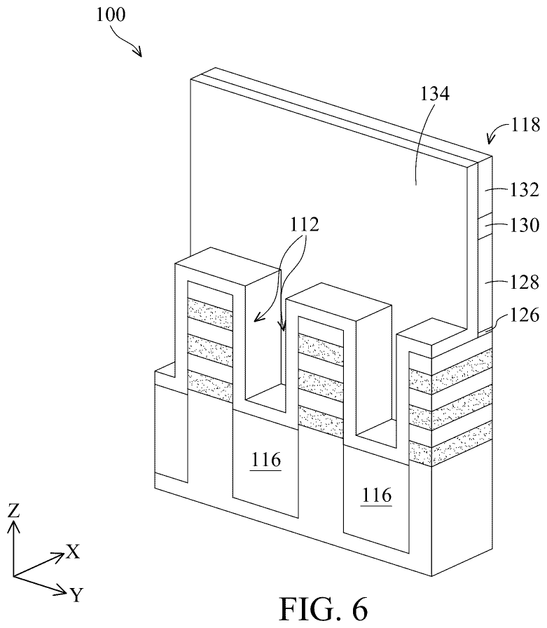

In FIG. 6, sacrificial gate structures 118 have been formed over the fins 112. The sacrificial gate structures 118 extend in the Y direction, perpendicular to the fins 112. Each sacrificial gate structure 118 crosses multiple fins 112. The sacrificial gate structures 118 are also formed in the trenches 110. FIG. 6 illustrates only a single sacrificial gate structure 118. However, in practice, a plurality of sacrificial gate structures 118 are formed extending parallel to each other in the Y direction.

The sacrificial gate structures 118 include a dielectric layer 126. In an exemplary embodiment, the dielectric layer 126 includes silicon oxide and may be termed a dummy gate oxide layer. However, alternatively, the dielectric layer 126 can include SiN, SiCN, SiOC, SiOCN, or other dielectric materials without departing from the scope of the present disclosure. In some embodiments, the dielectric layer 126 has a low K dielectric material. The dielectric layer 126 can be deposited by CVD, ALD, or PVD.

The sacrificial gate structures 118 include a sacrificial gate layer 128 on the dielectric layer 126. The sacrificial gate layer 128 can include materials that have a high etch selectivity with respect to the trench isolation regions 116. In an exemplary embodiment, sacrificial gate layer 128 includes polysilicon. However, the sacrificial gate layer 128 may be a conductive, semiconductive, or non-conductive material and may be or include amorphous silicon, poly-crystalline silicon-germanium (poly-SiGe), metallic nitrides, metallic silicides, metallic oxides, and metals. The sacrificial gate layer 128 may be deposited by physical vapor deposition (PVD), CVD, sputter deposition, or other techniques for depositing the selected material.

The sacrificial gate structures 118 include a dielectric layer 130 on the sacrificial gate layer 128 and a dielectric layer 132 of the dielectric layer 130. The dielectric layers 130 and 132 may correspond to first and second mask layers. The dielectric layer 130 can include silicon nitride, silicon oxynitride, or other suitable dielectric materials. The dielectric layer 130 can include silicon nitride, silicon oxynitride or other suitable dielectric materials. The dielectric layers 130 and 132 are different materials from each other and can be deposited using CVD, ALD, PVD, or other suitable deposition processes. Other materials and deposition processes can be utilized for the dielectric layers 130 and 132 without departing from the scope of the present disclosure.

Gate spacer layers 134 have been formed on the sidewalls of the layers 126, 128, 130, and 132. The gate spacer layers 134 may also be formed on other exposed surfaces of the integrated circuit. For example, portions of the gate spacer layer 134 are formed on the top surfaces of the fins 112, on sidewalls of the fins 112, and on top surfaces of the shallow trench isolation regions 116. The gate spacer layer 134 can include one or more of SiO, SiN, SiON, SiCN, SiOCN, SiOC, or other suitable dielectric materials. The gate spacer layer 134 can be formed by PVD, CVD, ALD, or other suitable deposition processes.

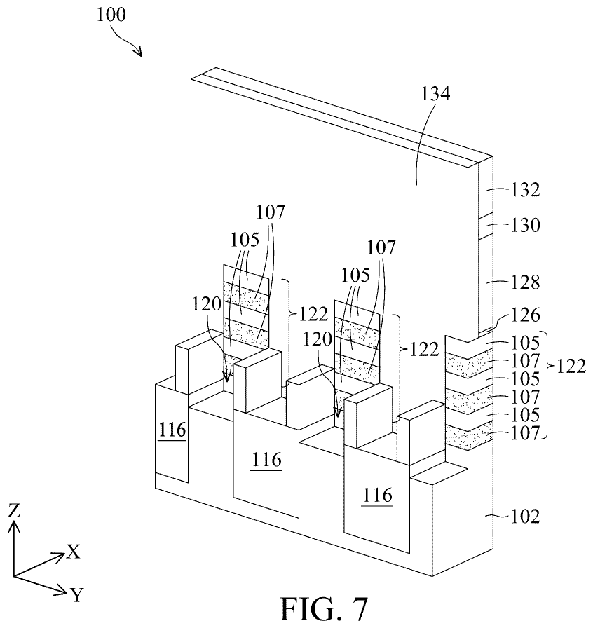

In FIG. 7, horizontal portions (e.g., in the X-Y plane) of the gate spacer layer 134 have been removed. In other words, portions of the gate spacer layer that are on the top surfaces of the stacks 112 and on the top surfaces of the shallow trench isolation regions 116. Vertically thicker portions of the gate spacer layer 134 remain on sidewalls of the fins 112. Removal of the portions of the gate spacer layer 134 can be accomplished via an anisotropic etching process, thereby exposing upper surfaces of the fins 112 and the trench isolation regions 116. After patterning of the gate spacer layers, vertically thicker portions of the gate spacer layers 134 remain, such as the portion shown in FIG. 4.

In FIG. 7, after removal of portions of the gate spacer layer 134, source/drain trenches 120 are formed in the fins 112. The sacrificial gate structures 118 and the gate spacer layer 134 are utilized as a mask for forming source/drain trenches 120 in the fins 112. In particular, one or more etching processes are performed to form the source/drain trenches 120 in the fins 112. Forming the source/drain trenches 120 includes etching through each of the semiconductor layers 104 and sacrificial semiconductor layers 106, and a portion of the substrate 102. Accordingly, the removal operations may include suitable etch operations for removing materials of the semiconductor layers 104, the sacrificial semiconductor layers 108, the substrate 102. The etching processes can include reactive ion etching (RIE), neutral beam etching (NBE), atomic layer etching (ALE), or the like.

Formation of the source/drain trenches 120 results in formation stacks 122 of channels 105. Each stack 122 of channels 105 corresponds to stacked channels of a transistor. Formation of the source/drain trenches 120 also results in formation of a plurality of sacrificial semiconductor nanostructures 107 from the sacrificial semiconductor layers 106. After formation of the source/drain trenches 120, the channels 105 and the sacrificial semiconductor nanostructures 107 may have substantially similar lateral dimensions.

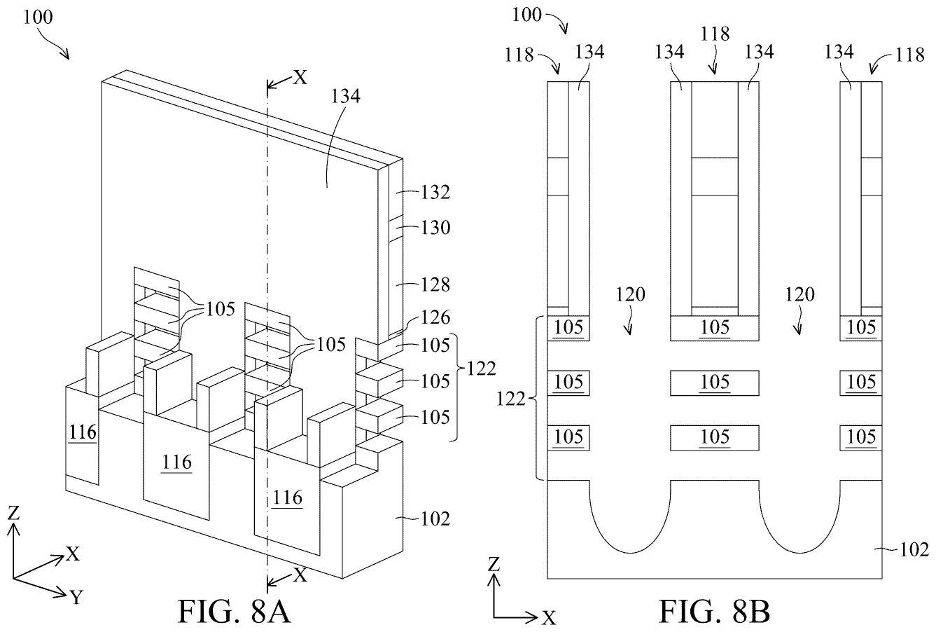

FIG. 8A is a perspective view of the integrated circuit 100, in accordance with some embodiments. FIG. 8B is a cross-sectional view of the integrated circuit 100 taken along cut lines X of FIG. 8A and at a same stage of processing as FIG. 8A, in accordance with some embodiments.

In FIGS. 8A and 8B, the sacrificial semiconductor nanostructures 107 have been removed. The sacrificial semiconductor nanostructures 107 can be removed by performing an etching process that selectively etches the material of the sacrificial semiconductor nanostructures 107 with respect to the material of the channels 105. As described previously, in one exemplary embodiment, the channels 105 are silicon and the sacrificial semiconductor nanostructures 107 are silicon germanium. The etching process selectively etches the silicon germanium of the sacrificial semiconductor nanostructures 107 with respect to the silicon of the channels 105. The result is that the sacrificial semiconductor nanostructures 107 are entirely removed and the channels 105 remain. As described previously, other materials can be utilized for the channels 105 and the sacrificial semiconductor nanostructures 107 without departing from the scope of the present disclosure.

The views of FIGS. 8A and 8B also illustrates that the source/drain trenches 120 extend into the substrate 102. In particular, the etching process that forms the source/drain trenches 120 also forms a recess in the substrate 102. As shown in FIG. 8B, the recess may be concave.

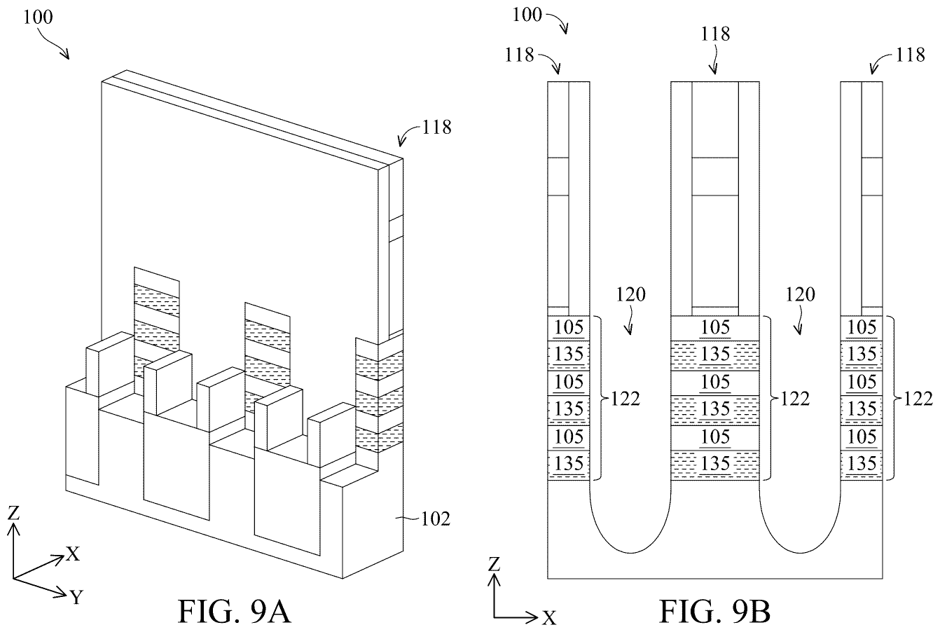

FIG. 9A is a perspective view of the integrated circuit 100, in accordance with some embodiments. FIG. 9B is a cross-sectional view of the integrated circuit 100 at a same stage of processing as FIG. 9A, in accordance with some embodiments.

FIGS. 9A and 9B, sacrificial dielectric nanostructures 135 have been formed in place of the sacrificial semiconductor nanostructures 107. Accordingly, the sacrificial dielectric nanostructures 135 are formed between adjacent channels 105. The lowest sacrificial dielectric nanostructures 135 of each stack 122 is between the substrate 102 and the lowest channel 105 of each stack 122. In an exemplary embodiment, the sacrificial dielectric nanostructures 135 include silicon oxide. Alternatively, the sacrificial dielectric nanostructures 125 can include, SiON, SiCN, SiOCN, SiOC, or other suitable dielectric materials.

In some embodiments, the sacrificial dielectric nanostructures 135 are formed by depositing a dielectric material in the source/drain trenches 120. The dielectric material also fills the spaces between the channels 105 left by removal of the sacrificial semiconductor nanostructures 107. The dielectric material can be deposited by CVD, ALD, PVD, or other suitable deposition processes. After deposition of the dielectric material, an etching process is performed utilizing the gate spacer layers 134 as a mask. The etching process is an anisotropic etching process that selectively etches in the downward direction. The result is that the dielectric material is removed from the source/drain trenches 120 and remains only as the dielectric nanostructures 135 between the channels 105.

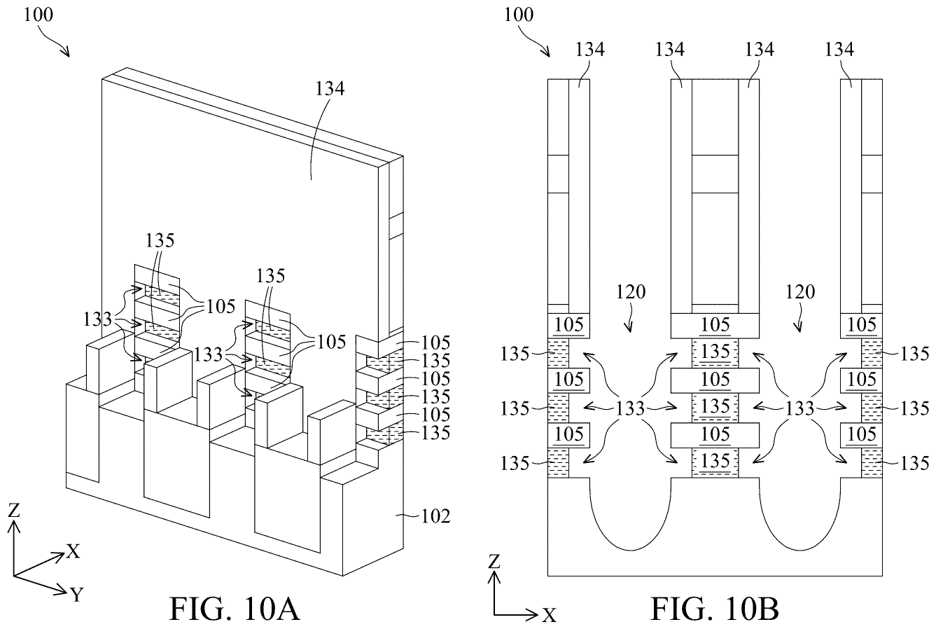

FIG. 10A is a perspective view of the integrated circuit 100, in accordance with some embodiments. FIG. 10B is a cross-sectional view of the integrated circuit 100 at a same stage of processing as FIG. 10A, in accordance with some embodiments.

In FIGS. 10A and 10B, an etching process has been performed to form recesses 133 in the dielectric nanostructures 135. In particular, an isotropic etching process is performed that selectively etches the material of the dielectric nanostructures 135 with respect to other exposed materials. The etching process is timed so as to remove end portions of the dielectric nanostructures 135 without entirely removing the dielectric nanostructures 135. The result is that recesses 133 are formed in the dielectric nanostructures 135 between adjacent channels 105. In other words, the ends of the dielectric nanostructures 135 are recessed relative to the ends of the channels 105.

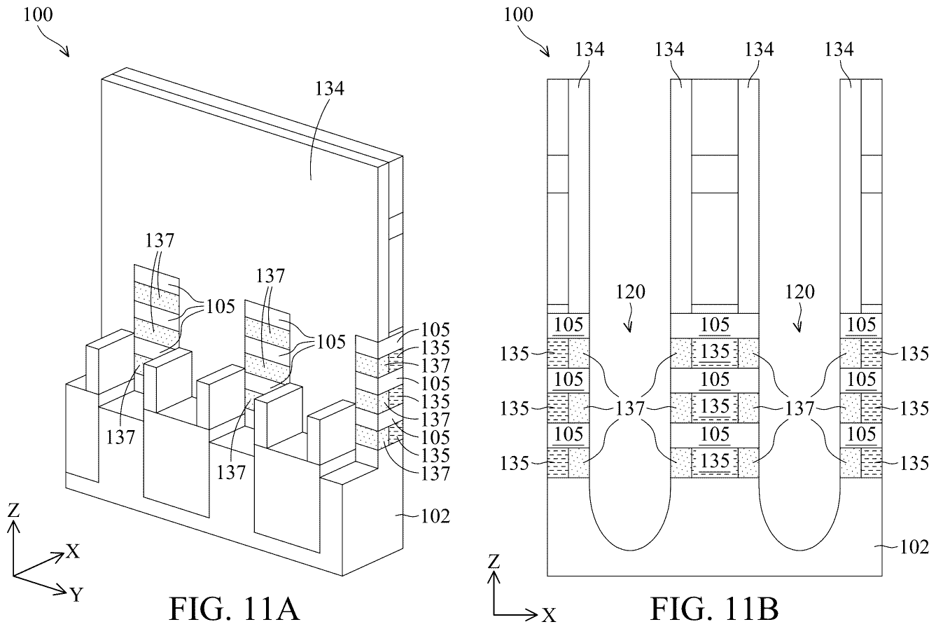

FIG. 11A is a perspective view of the integrated circuit 100, in accordance with some embodiments. FIG. 11B is a cross-sectional view of the integrated circuit 100 at a same stage of processing as FIG. 11A, in accordance with some embodiments.

In FIGS. 11A and 11B, semiconductor structures 137 have been formed in the recesses 133. In particular, an epitaxial growth process has been performed to grow the semiconductor structures 137 from the channels 105. In an exemplary embodiment, the semiconductor structures 137 include silicon germanium. However, other semiconductor materials can be utilized without departing from the scope of the present disclosure. The semiconductor structures may be termed sacrificial semiconductor inner spacers because dielectric inner spacers will be formed in place of the sacrificial semiconductor inner spacers.

In practice, after the epitaxial growth process to form the semiconductor structures 139, the semiconductor material extends into the source/drain trenches 120. Accordingly, an anisotropic etching process is performed that selectively removes the semiconductor material of the semiconductor structures 139 in the vertical direction so that only the portions covered by the channels 105 remain.

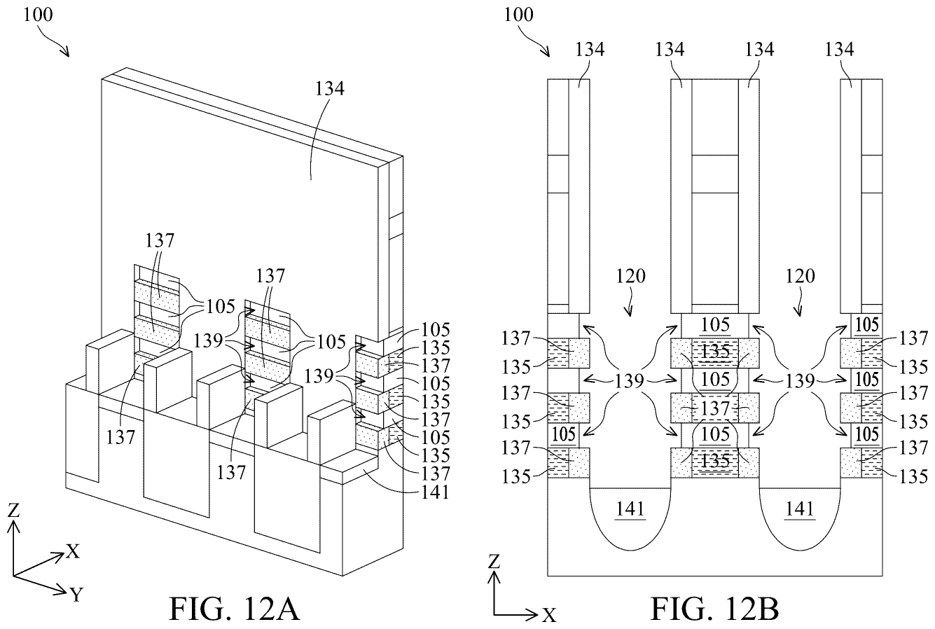

FIG. 12A is a perspective view of the integrated circuit 100, in accordance with some embodiments. FIG. 12B is a cross-sectional view of the integrated circuit 100 at a same stage of processing as FIG. 12A, in accordance with some embodiments.

In FIGS. 12A and 12B, recesses 139 have been formed in the channels 105. In particular, an etching process has been performed to form recesses 139 in the channels 105. In particular, an isotropic etching process is performed that selectively etches the material of the channels 105 with respect to other exposed materials. The etching process is timed so as to remove end portions of the channels 105 without entirely removing the channels 105. The result is that recesses 139 are formed in the channels 105. In other words, the ends of the channels 105 are recessed relative to the ends of the semiconductor structures 137. In some embodiments, the recesses 139 are not formed, resulting in a straight vertical sidewall of the channels 105 and the semiconductor structures 137.

In FIGS. 12A and 12B, a bottom semiconductor layer 141 has been formed in the bottom of the trenches 120 in the concave recesses formed in the substrate 102. The bottom semiconductor layer can include intrinsics semiconductor material such as undoped silicon, undoped silicon germanium or other semiconductor materials.

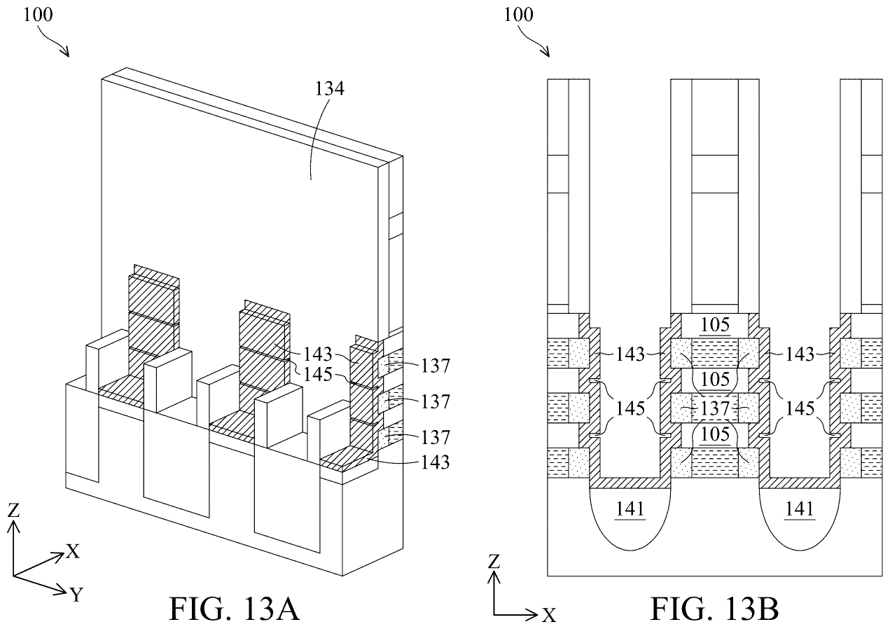

FIG. 13A is a perspective view of the integrated circuit 100, in accordance with some embodiments. FIG. 13B is a cross-sectional view of the integrated circuit 100 at a same stage of processing as FIG. 13A, in accordance with some embodiments.

In FIGS. 13A and 13B, a continuous semiconductor seed layer 143 has been formed in the source/drain trenches 120 and in the recesses 139. The semiconductor seed layer 143 can be formed on exposed surfaces of the channels 105, the semiconductor structures 137, and the bottom semiconductor layer 141. In some embodiments, the semiconductor seed layer includes silicon. The silicon may be doped with boron, gallium, or other dopant species. In some embodiments, the semiconductor seed layer 141 can include silicon germanium. The silicon germanium can include between 10% and 30% germanium and may be doped with boron, gallium, or other dopant species. The semiconductor seed layer 141 can have a thickness between 0.5 nm and 10 nm. Other materials and thicknesses can be utilized for the semiconductor seed layer without departing from the scope of the present disclosure.

In some embodiments, seams 145 are formed in the semiconductor seed layer 141. Seams 145 can result from the presence of the recesses 139 and the channels 105. The seams 145 may correspond to slots or gaps that form adjacent to the recesses 139. In some embodiments, the recesses 139 are not formed. This may result in an absence of seams 139 in the semiconductor seed layer 141.

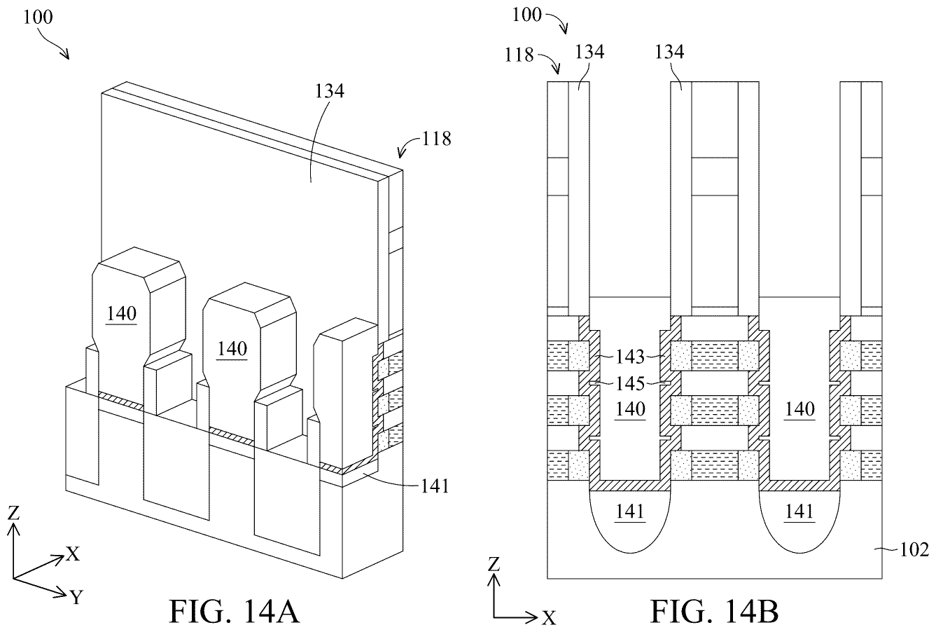

FIG. 14A is a perspective view of the integrated circuit 100, in accordance with some embodiments. FIG. 14B is a cross-sectional view of the integrated circuit 100 at a same stage of processing as FIG. 14A, in accordance with some embodiments.

In FIGS. 14A and 14B, source/drain regions 140 have been formed. In the illustrated embodiment, the source/drain regions 140 are epitaxially grown from the accuracy layer 141. The source/drain regions 140 fill the source/drain trenches 120. For each stack 122 of channels 105, there are two source/drain regions 140. Each channel 105 of a stack 122 extends between adjacent source/drain regions 140. The semiconductor seed layer 141 may be considered part of the source/drain regions 140. Some stacks 122 of channels 105 may share a source/drain 140 with a stack 122 of channels 105 that is adjacent in the X direction.

As can be seen in FIG. 14A, the source/drain regions 140 grow over portions of the gate spacer layer 134. Lower portions of the source/drain regions 140 are founded in the Y direction by the remnants of the gate spacer layer 134 on the surface of the trench isolation regions 116.

In some embodiments, the source/drain regions 140 exert beneficial stress on the respective channels 105, thereby improving performance. Furthermore, because the source/drain regions 140 are grown from the continuous semiconductor seed layer 143, the source/drain regions 140 of high quality and fewer defects. Furthermore, the epitaxial growth can fully cover the channel ends with a smaller epitaxial volume. In some embodiments, the width of lateral growth of the source/drain regions 140 can be between 0 nm and 15 nm. In some embodiments, the reduced volume of the source/drain regions 140 can result in narrower oxide diffusion (OD) spaces that define active regions. For example, OD spaces in accordance with some embodiments of the present disclosure can be between 0 nm and 15 nm narrower than other solutions which may have an OD range between 20 nm and 50 nm. In some embodiments, the continuous semiconductor seed layer 143 is silicon.

The source/drain regions 140 may include any acceptable material, such as appropriate for n-type or p-type devices. For n-type devices, the source/drain regions 140 include materials exerting a tensile strain in the channel regions, such as silicon, SiC, SiCP, SiP, or the like, in some embodiments. When p-type devices are formed, the source/drain regions 140 include materials exerting a compressive strain in the channel regions, such as SiGe, SiGeB, Ge, GeSn, or the like, in accordance with certain embodiments. The source/drain regions 140 may have surfaces raised from respective surfaces of the fins and may have facets. Neighboring source/drain regions 140 may merge in some embodiments to form a singular source/drain region 140 over two neighboring fins of the fins 112.

The source/drain regions 140 may be implanted with dopants followed by an annealing process. The source/drain regions 140 may have an impurity concentration of between about 10¹⁹ cm⁻³ and about 10²¹ cm⁻³. N-type and/or p-type impurities for source/drain regions 140 may be any of the impurities previously discussed. In some embodiments, the source/drain regions 140 are in situ doped during growth.

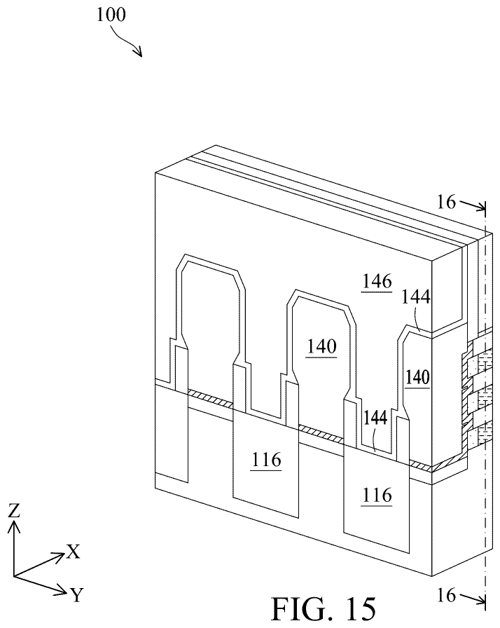

FIG. 15 is a perspective view of the integrated circuit 100, in accordance with some embodiments. In FIG. 15, a contact etch stop layer (CESL) 144 and an interlevel dielectric (ILD) 146 have been formed. The CESL layer 144 can include a thin dielectric layer conformally deposited on exposed surfaces of the source/drain regions 140, the trench isolation region 116, the gate spacer layer 134, and on other exposed surfaces. The CESL layer 144 can include SiN, SiC, SiOC, SiOCN, SiON, or other suitable dielectric materials. The CESL 144 can be deposited by CVD, ALD, PVD, or other suitable deposition processes.

The dielectric layer 146 covers the CESL 144. The dielectric layer 146 can include SiO, SiON, SiN, SiC, SiOC, SiOCN, SiON, or other suitable dielectric materials. The dielectric layer 146 can be deposited by CVD, ALD, PVD, or other suitable deposition processes.

In some embodiments, the presence of the semiconductor seed layer 143 results in a better U % of growth of the source/drain regions 140 which can fully cover the channel ends. In other words, the source/drain regions 140 occupy a lower lateral volume, which is beneficial to reduction of parasitic capacitance and OD space scaling. Furthermore, this can lead to shorter epitaxial growth process to reduce the cost of epitaxial growth processes. This can also lead to reduced gate-to-drain capacitance due to oxide inner spacers in finished device. This can be seen primarily in FIG. 14A in which the source/drain regions 140 do not protrude pass an outer edge of the lower portions of the gate spacer layers 134. This results in a reduced gate to source/drain capacitance and in a reduction of active region space scaling, as will be described in more detail below. In some embodiments, the use of the seed layer 143 results in high quality source/drain regions with fewer defects and high beneficial strain to enhance performance of P-type transistors.

In FIG. 15, a CMP process has been performed to reduce the height of the sacrificial gate structures 118. The results of the CMP process is that the dielectric layers 130 and 132 are entirely removed. The heights of the sacrificial gate layer 128, the gate spacer layers 134, the CESL layer 144, and the dielectric layer 146 have been reduced and the top surfaces have been planarized. In some embodiments, the process for forming the source/drain regions 140 results in narrower OD dimensions. Corresponding to the dimension in the Y direction of the trench isolation regions 116 between upper protruding portions of the substrate 102. This can be achieved because the lateral width of the source/drain regions is constrained, as described previously. This reduces the risk of bridging between source/drain regions adjacent to each other in the Y direction. The reduced risk of bridging allows for smaller OD dimensions. Furthermore, the outer edge of the source/drain regions 140, as shown in FIG. 15, protrudes only a small distance in the Y direction further than the inner edge of the adjacent lower portions of the gate spacer layers 134. In some embodiments, the outer edge of the source/drain regions 140 do not protrude beyond the outer edge of the lower portions of the gate spacer layers 134.

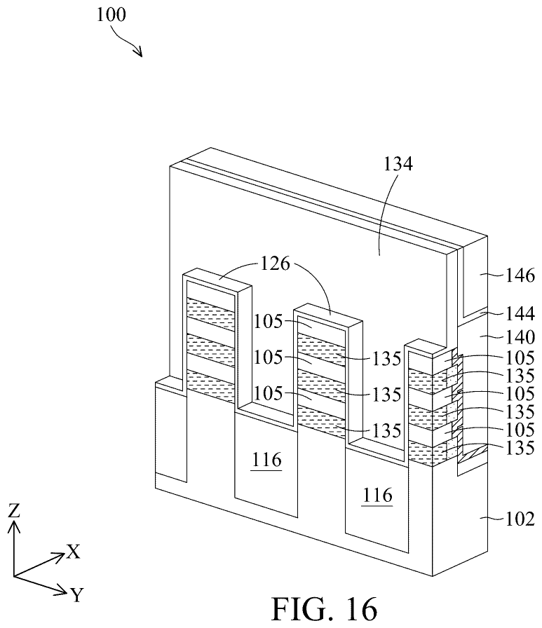

FIG. 16 is a perspective view of the integrated circuit 100 taken along cut lines 16 of FIG. 15, in accordance with some embodiments. In FIG. 16, the sacrificial gate structures 118 have been removed from between the gate spacer layers 134. In particular, the dielectric layer 126 and the sacrificial gate layer 128 have been entirely removed from between the gate spacer layers 134.

In some embodiments, the sacrificial gate layer 128 is removed by an anisotropic dry etch process. For example, the etching process may include a dry etch process using reaction gases that selectively etch the sacrificial gate layer 128 without etching the spacer layer 134. The dielectric layer 126, when present, may be used as an etch stop layer when the sacrificial gate layer 128 is etched. The dielectric layer 126 may then be removed after the removal of the sacrificial gate layer 128.

Removal of the sacrificial gate layer 128 and the dielectric layer 126 results in the formation of a void between the gate spacer layers 134 above the channels 105. As will be set forth in more detail below, an upper portion of a gate metal or gate electrode will be formed in the void. Accordingly, the sacrificial gate layer 128 is sacrificial in the sense that the upper portion of the gate metal will eventually be formed in its place.

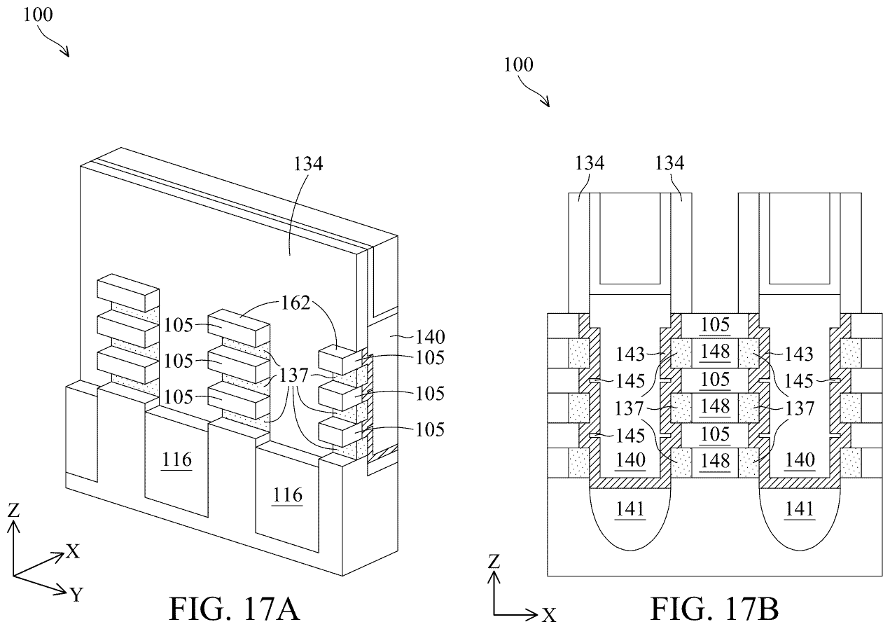

FIG. 17A is a perspective view of the integrated circuit 100, in accordance with some embodiments. FIG. 17B is a cross-sectional view of the integrated circuit 100 at a same stage of processing as FIG. 17A, in accordance with some embodiments. The view of FIG. 17A is taken on the same cut lines as FIG. 16.

In FIGS. 17A and 17B, the channels 105 are released by removal of the dielectric nanostructures 135. The dielectric nanostructures 135 can be removed by a selective etching process using an etchant that is selective to the material of the dielectric nanostructures 135, such that the dielectric nanostructures 135 are removed without substantially etching the channels 105 or the semiconductor structures 137. Removal of the dielectric nanostructures 135 results in the formation of voids 148 between the channels 105.

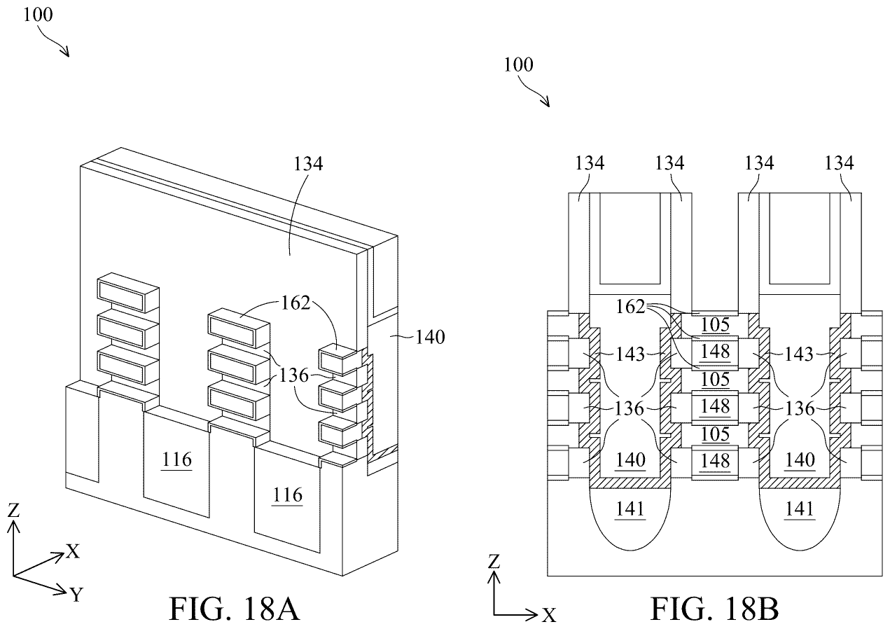

FIG. 18A is a perspective view of the integrated circuit 100, in accordance with some embodiments. FIG. 18B is a cross-sectional view of the integrated circuit 100 at a same stage of processing as FIG. 18A, in accordance with some embodiments. The view of FIG. 18A is taken on the same cut lines as FIG. 16.

In FIGS. 18A and 18B, the dielectric inner spacers 136 are formed from the semiconductor structures 137, in accordance with some embodiments. In particular, the semiconductor structures 137 are converted to dielectric inner spacers 136. In one example, an oxidizing process is performed in order to oxidize the semiconductor structures 137 to convert them to dielectric inner spacers 136.

In some embodiments, the oxidizing process includes generating and performing a furnace oxidation in a presence of the plasma. In some embodiments, the plasma is generated between 500° C. and 800° C. A furnace oxidation is performed in the presence of the plasma in order to convert or replace the semiconductor structure to a dielectric inner spacer 136. In some embodiments, the semiconductor structure 137 include silicon germanium. The oxidizing process converts the silicon germanium to silicon germanium oxide. In some embodiments, the concentration of germanium is greater than or equal to 0% and less than or equal to 50%. In some embodiments, the semiconductor structures 137 include silicon and the oxidizing process results in silicon oxide dielectric inner spacers 136. Other types of semiconductors can be utilized without departing from the scope of the present disclosure. In some embodiments, the furnace oxidation process utilizes H2/O2 gas. In some embodiments, the inner spacers 136 include SiO as Ge can be scavenged into gas byproduct by the furnace oxidation process or by the subsequent H2 annealing process. In some embodiments, the annealing process is not performed.

In some embodiments, the oxidizing process results in porous dielectric inner spacers 136 due to the use of high energy plasma. This may further reduce the dielectric constant of the dielectric inner spacers. This further reduces the gate to source/drain capacitance and results in higher switching speeds of the transistors 101.

In some embodiments, the dielectric inner spacers 136 have a width in the X direction between 1 nm and 15 nm. In some embodiments, the dielectric inner spacers 136 have a height dimension in the Z direction between 1 nm and 15 nm. In some embodiments, the dielectric inner spacer has a flat outer surface. In some embodiments, the dielectric inner spacer 136 protrudes outward toward the source/drain region 140. The protrusion can extend between 1 nm and 10 nm. In some embodiments, the dielectric inner spacers 136 have a flat inner surface. In some embodiments, the dielectric inner spacers 136 protrude into the gap 148 with the protrusion depth between 1 nm and 10 nm.

In some embodiments, dielectric inner spacers 136 also results in formation of an interfacial dielectric layer 162 on exposed surfaces of the channels 105. The interfacial dielectric layer 162 is part of a gate dielectric, as will be set forth in more detail below.

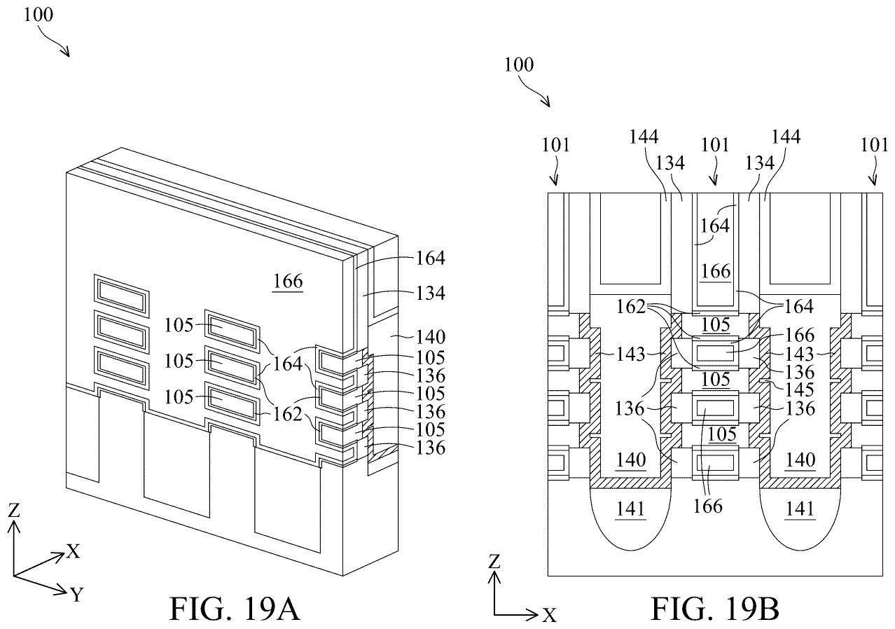

FIG. 19A is a perspective view of the integrated circuit 100, in accordance with some embodiments. FIG. 19B is a cross-sectional view of the integrated circuit 100 at a same stage of processing as FIG. 19A, in accordance with some embodiments. The view of FIG. 19A is taken on the same cut lines as FIG. 16.

In FIGS. 19A and 19B, the interfacial dielectric layer 162, a high-K dielectric layer 164, and the gate metal 166 have been formed, in accordance with some embodiments. The interfacial gate dielectric layer 162 can be formed as described in relation to FIGS. 18A and 18B, or in a separate process.

The interfacial gate dielectric layer 162 is deposited on all exposed surfaces of the channels 105. The interfacial gate dielectric layer 162 is wrapped around the channels 105. The interfacial gate dielectric layer 162 can include a dielectric material such as silicon oxide, silicon nitride, or other suitable dielectric materials. The interfacial gate dielectric layer 162 can include a comparatively low-K dielectric with respect to high-K dielectric such as hafnium oxide or other high-K dielectric materials that may be used in gate dielectrics of transistors. High-K dielectrics can include dielectric materials with a dielectric constant higher than the dielectric constant of silicon oxide. The interfacial gate dielectric layer 162 can be formed by a thermal oxidation process, a chemical vapor deposition (CVD) process, or an atomic layer deposition (ALD) process. The interfacial gate dielectric layer 162 can have a thickness between 0.5 nm and 2 nm. Other materials, deposition processes, and thicknesses can be utilized for the interfacial gate dielectric layer 162 without departing from the scope of the present disclosure.

The high-K dielectric layer 164 is deposited in a conformal deposition process. The conformal deposition process deposits the high-K dielectric layer 164 on the interfacial gate dielectric layer 162, on the substrate 102, on the trench isolation regions 116, and on the gate spacer layers 134. The high-K gate dielectric layer 164 is wrapped around the channels 105. The high-K gate dielectric layer 164 has a thickness between 1 nm and 3 nm. The high-K dielectric layer includes one or more layers of a dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The high-K dielectric layer 164 may be formed by CVD, ALD, or any suitable method. Other thicknesses, deposition processes, and materials can be utilized for the high-K dielectric layer 164 without departing from the scope of the present disclosure. The high-K dielectric layer 164 is a gate dielectric layer.

The gate metal 166 is deposited on all exposed surfaces of the high-K dielectric layer 164. The gate metal 166 is wrapped around the channels 105. Although the gate metal 166 is shown as a single layer in FIGS. 19A and 19B, in practice, the gate metal 166 can include one or more conductive liner layers, work function layers, and gate fill layers that collectively make up the gate metal. The gate metal can include one or more of Ti, TiN, Ta, TaN, Al, Cu, Co, Ru, W, Au, or other suitable conductive materials. The gate metal 166 can be deposited by PVD, ALD, or CVD. Other configurations, materials, and deposition processes can be utilized for the gate metal 166 without departing from the scope of the present disclosure.

At the stage of processing shown in FIGS. 19A and 19B, the transistors 101 are substantially complete. Each transistor 101 includes a stack 122 of channels 105 extending between the source/drain regions 140 and acting as stacked channels of the transistor 101. The gate metal 166 acts as a gate electrode surrounding the channels 105.

In FIG. 19A, there are no breaks in the gate metal 166, such that the gate electrodes of adjacent transistors 101 are all shorted together. Though not shown in FIG. 19B, in further processing steps, cut-gate processes may be performed to electrically isolate portions of the gate metal 166 to form electrically isolated gate electrodes for the transistors 101.

Though not shown in FIGS. 19A and 19B, source/drain contacts may also be formed. Trenches can be formed in the dielectric layers 144 and 146 to expose the top surfaces of the source/drain regions 140. A silicide may be formed on the exposed portions of the source/drain regions 140. The conductive via or plug can be formed in contact with the silicide. The voltages can be applied to source/drain regions 140, or currents can be passed via the source/drain contacts.

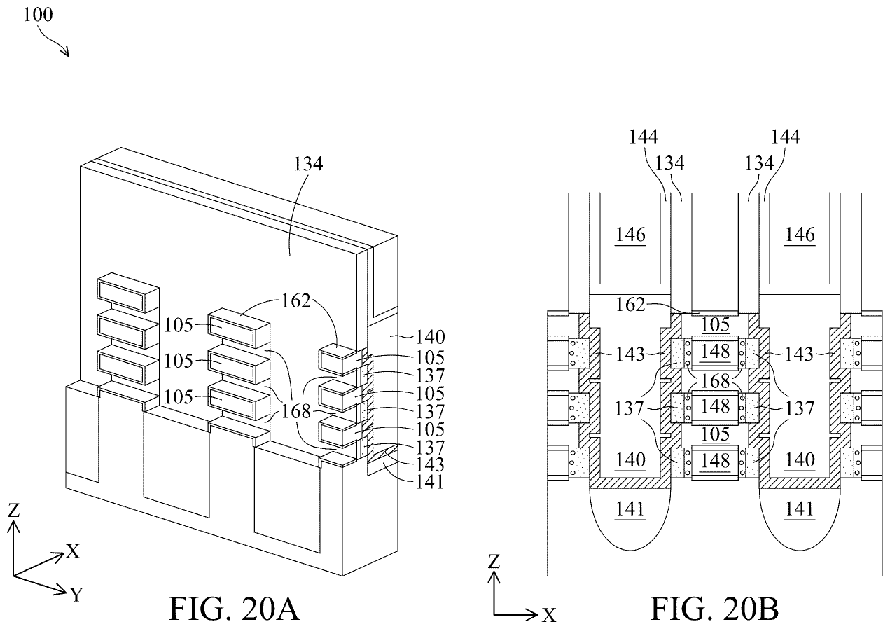

FIGS. 20A-22B illustrate a process for forming a transistor 101 of an integrated circuit 100 in accordance with some embodiments. The process of FIGS. 20A-22B can be substantially similar to the process shown and described in relation to FIGS. 1-17B.

FIG. 20A is a perspective view of the integrated circuit 100, in accordance with some embodiments. FIG. 20B is a cross-sectional view of the integrated circuit 100 at a same stage of processing as FIG. 20A, in accordance with some embodiments.

In FIGS. 20A and 20B, a plurality of porous dielectric membranes 168 have been formed from inner end portions of the semiconductor structures 137. The porous dielectric membranes 168 are formed by performing an oxidizing process in the presence of the semiconductor structures 137. The oxidizing process can include generating a plasma in a presence of the semiconductor structures 137. Generation of the plasma can include raising the temperature to between 200° C. and 400° C., though other temperature ranges can be utilized without departing from the scope of the present disclosure. An oxidant is introduced to assist in the oxidizing process in conjunction with the plasma. The result of this process is that inner ends of the semiconductor structures 137 become dielectric material. In some embodiments, the plasma is generated using a combination of a magnetic field and microwave radiation to ionize a gas. In some embodiments, the plasma can be generated with an electron cyclotron resonance tool, a plasma enhanced CVD tool, or other suitable tools. In some embodiments, oxygen is used to form the plasma.

Furthermore, pores are formed throughout the dielectric material. The size of the pores is sufficient to enable removal of the remaining portion of the semiconductor structures 137 in a subsequent etching process. The pores are sufficiently small to ensure that materials for forming the high-K dielectric 164 do not pass through the porous dielectric membranes 137. In some embodiments, the pore size is between 0.5 nm and 1.5 nm, though other dimensions can be utilized without departing from the scope of the present disclosure. In some embodiments, with a thin oxide layer there will be pin holes through which the etching gas can penetrate to remove the semiconductor structures 137.

In some embodiments, the porous dielectric membranes 168 may be termed semipermeable dielectric layers or semipermeable dielectric structures. In some embodiments, the porous dielectric membranes 168 can include silicon oxide. In these cases, the semiconductor structures 137 are silicon. In some embodiments, the porous dielectric membranes 168 can include silicon germanium oxide with a concentration of germanium between 0% and 60%. In these cases, the structures 130 are silicon germanium. In some embodiments, the thickness of the porous dielectric membranes 168 in the X direction is between 1 nm and 5 nm. Other materials, dimensions, and processes can be utilized in forming the porous dielectric membranes 168 without departing from the scope of the present disclosure.

In FIGS. 20A and 20B, an interfacial dielectric layer 162 is also formed channels 105. The interfacial dielectric layer 162 can result from the oxidizing process or from other processes. The interfacial dielectric layer 162 can have materials and properties described previously.

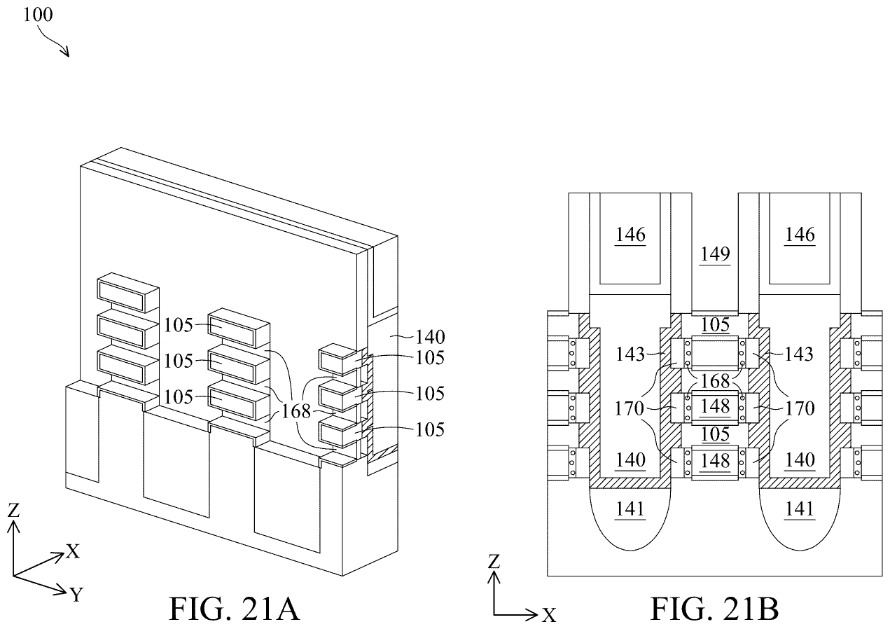

FIG. 21A is a perspective view of the integrated circuit 100, in accordance with some embodiments. FIG. 21B is a cross-sectional view of the integrated circuit 100 at a same stage of processing as FIG. 21A, in accordance with some embodiments.

In FIGS. 21A and 21B, the dielectric inner spacers 170 has been formed. The dielectric inner spacers 170 are formed by performing an etching process in the presence of the porous dielectric membranes 168. The etching process selectively etches the material of the remaining portions of the semiconductor structures 137. As previously described, an inner end portion of the semiconductor structures 137 has been converted to porous dielectric membranes 168. However, remaining portions of the semiconductor structures 137 remain semiconductor material. In FIGS. 21A and 21B, the etching process selectively etches the material of the semiconductor structures 137 with respect to the semiconductor material of the channels 105 and the seed layer 143 in order to completely remove the remaining portions of the semiconductor structures 137.

In some embodiments, the porous dielectric membranes 168 enable etchant materials can pass through the porous dielectric membranes 168 to contact the semiconductor structures 137. The etchant materials etch the semiconductor structures 137. The resulting material is removed through the porous dielectric membranes 168 through the pores of the porous dielectric membranes 168.

The result of the etching process is that gaps are formed in place of the semiconductor structures 137. The gaps between the porous dielectric membranes 168 and the semiconductor seed layer 143. In some embodiments, the gaps are filled with a fluid such as air or another fluid or gas that results in a low dielectric constant. Accordingly, the dielectric inner spacers 170 are gaps with a very low dielectric constant. In embodiments in which the dielectric inner spacers 170 are filled with air, the dielectric constant of the dielectric inner spacers 170 approaches 1. In particular, the dielectric constant of air at room temperature is about 1.0006, which is far lower than typical solid dielectric materials. In some embodiments, the dielectric inner spacers 170 may be termed gaseous dielectric inner spacers, fluidic dielectric inner spacers, hollow inner spacers, or air dielectric inner spacers.

In some embodiments, the dielectric inner spacers 170 may occupy a portion of the source/drain region 140. In some embodiments, the dielectric inner spacers 170 can be between 1 nm and 15 nm wide in the X direction in between 1 nm and 15 nm hi in the Y direction. The shape of the dielectric inner spacers 170 can be flat or can protrude toward the source/drain regions 140 with a protrusion depth between 1 nm and 10 nm. The shape of the dielectric inner spacers 170 on the inner and can be flat or can protrude toward the gate metal 166 (subsequently formed) with a protrusion depth between 1 nm and 10 nm. In some embodiments, due to the very low dielectric constant of the dielectric inner spacers 170, the gate to source/drain capacitance is very low. This results in higher switching speeds in the overall better performance of the transistors 101. In some embodiments, the reduced volume of the source/drain regions 140 can result in narrower OD spaces. For example, OD spaces in accordance with some embodiments of the present disclosure can be between 0 nm and 15 nm narrower than other solutions which may have an OD range between 20 nm and 50 nm.

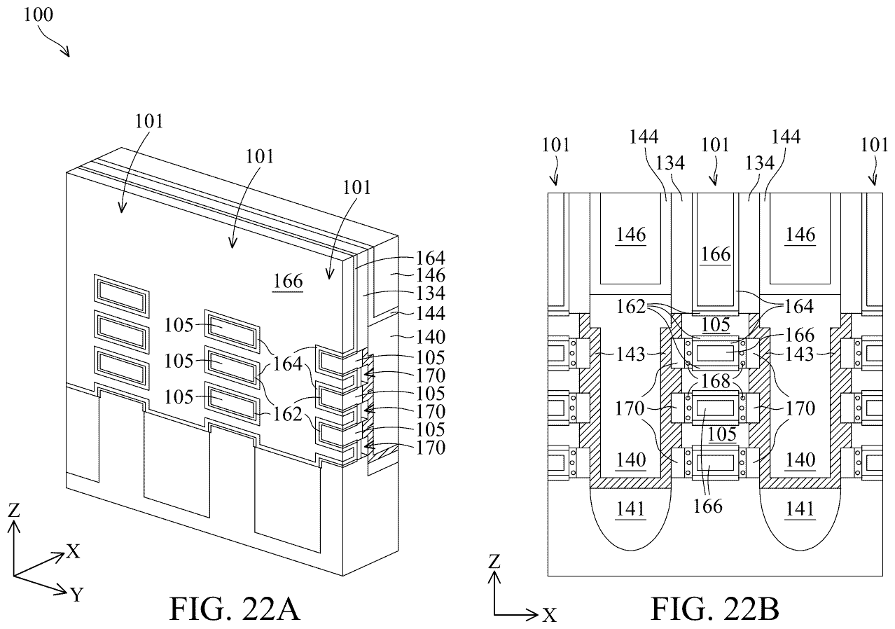

FIG. 22A is a perspective view of the integrated circuit 100, in accordance with some embodiments. FIG. 22B is a cross-sectional view of the integrated circuit 100 at a same stage of processing as FIG. 22A, in accordance with some embodiments.

In FIGS. 22A and 22B, the interfacial dielectric layer 162, the high-K dielectric layer 164, and the gate metal 166 have been formed. The interfacial dielectric layer 162, the high-K dielectric layer 164, and the gate metal 166 can be formed as described previously. The high-K dielectric layer 164 lines the channels 105, the interior surfaces of the porous dielectric membranes 168, and the gate spacer layers 134. As described previously, the pores of the porous dielectric membranes 168 did not enable the materials or precursors of the high-K dielectric layer 164 can pass into the dielectric inner spacers 170. Accordingly, as described previously, the porous dielectric membranes 168 are semipermeable dielectric structures.

The gate metal 166 wraps around the channels 105. The gate metal is separated from the source/drain regions 140 by the porous dielectric membranes 168 and the dielectric inner spacers 170. Due to the low dielectric constant of the porous dielectric membranes 168 and the dielectric inner spacers 170, there is a low gate to source/drain capacitance. In some embodiments, the porous dielectric membranes 168 may be considered part of the dielectric inner spacers 170.

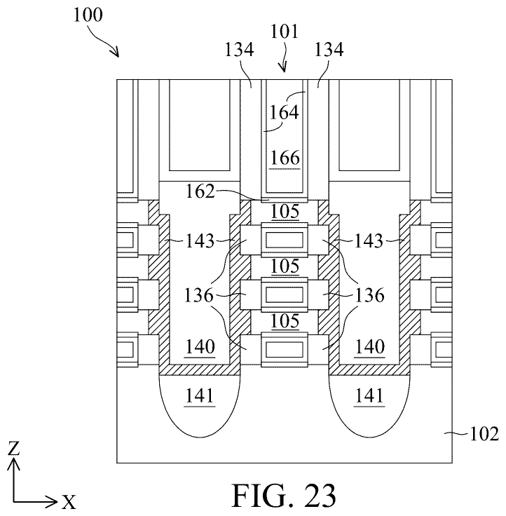

FIG. 23 is a cross-sectional view of an integrated circuit 100, in accordance with some embodiments. In FIG. 23, the semiconductor seed layer 143 does not include seams 145. Instead, the sidewall of the semiconductor seed layer 143 is vertically straight without ridges or seams. Accordingly, the source/drain region 140 does not include protrusions into seams. Instead, the source/drain regions 140 have substantially vertical sidewalls apart from a step at the top channel 105 of each stack.

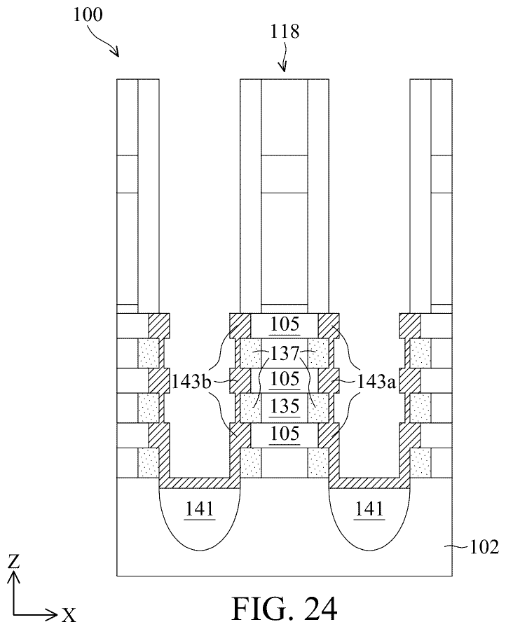

FIG. 24 is a cross-sectional view of an integrated circuit 100, in accordance with some embodiments. FIG. 24 illustrates a stage of processing after which the semiconductor seed layer 143 has been formed. In some embodiments, the semiconductor seed layer grows preferentially on the channels 105. The result is that the semiconductor seed layer 143 grows thicker on the ends of the channels 105 that on the ends of the semiconductor structures 137. Accordingly, the semiconductor seed layer 143 has a stepped structure thinner and thicker portions as shown in FIG. 24. In some embodiments, the semiconductor seed layer 143 has a thickness between 2 nm and 6 nm on the ends of the channels 105. In some embodiments, the semiconductor seed layer 143 has a thickness between 0.5 nm and 3 nm on the ends of the semiconductor structures 137 and, on the outer ends of the dielectric inner spacers 136/170 that will be formed in place of the semiconductor structures 137.

In some embodiments, the recessing of the channels 105 as shown and described in relation to FIGS. 12A and 12B is not performed. Accordingly, the surfaces of the channels 105 and the semiconductor structures 137 may be substantially coplanar with each other. This can result in a semiconductor seed layer 143 having a substantially vertical sidewall or having a stepped structure if the semiconductor seed layer 143 grows preferentially faster on the channels 105 or the semiconductor structures 137.

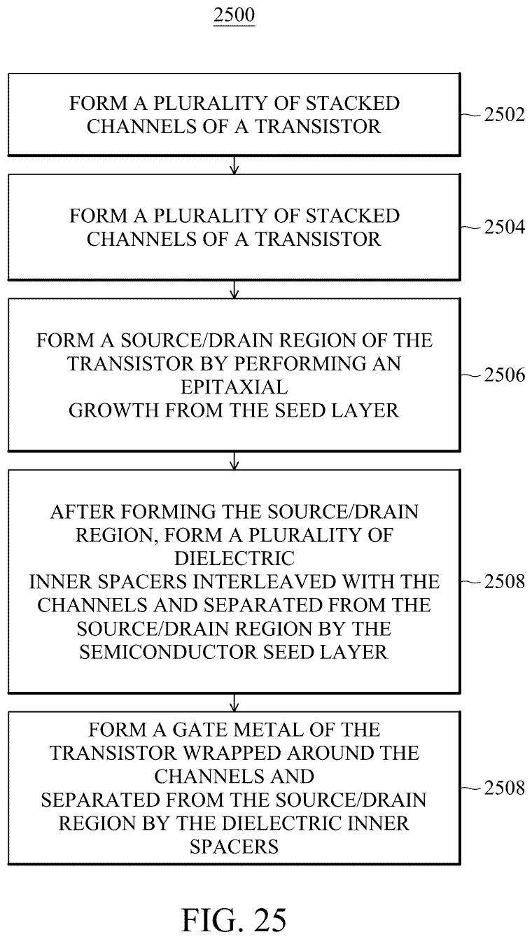

FIG. 25 is a flow diagram of a method 2500 for forming an integrated circuit, in accordance with some embodiments. The method 2500 can utilize the structures, processes, and systems described in relation to FIGS. 1-24. At 2502, the method 2500 includes forming a plurality of stacked channels of a transistor. One example of a transistor is the transistor is the transistor 101 of FIG. 19B. One example of stacked channels are the stacked channels 105 of FIG. 19B. At 2504, the method 2500 includes forming a semiconductor seed layer on ends of the stacked channels. One example of a seed layer is the seed layer 143 of FIG. 19B. At 2506, the method 2500 includes forming a source/drain region of the transistor by performing an epitaxial growth from the seed layer. One example of a source/drain region is the source/drain region 140 of FIG. 19B. At 2508, the method 2500 includes after forming the source/drain region, forming a plurality of dielectric inner spacers interleaved with the channels and separated from the source/drain region by the semiconductor seed layer. One example of dielectric inner spacers is the dielectric inner spacers of FIG. 19B. At 2510, the method 2500 includes forming a gate metal of the transistor wrapped around the channels and separated from the source/drain region by the dielectric inner spacers. One example of a gate metal is the gate metal 166 of FIG. 19B.

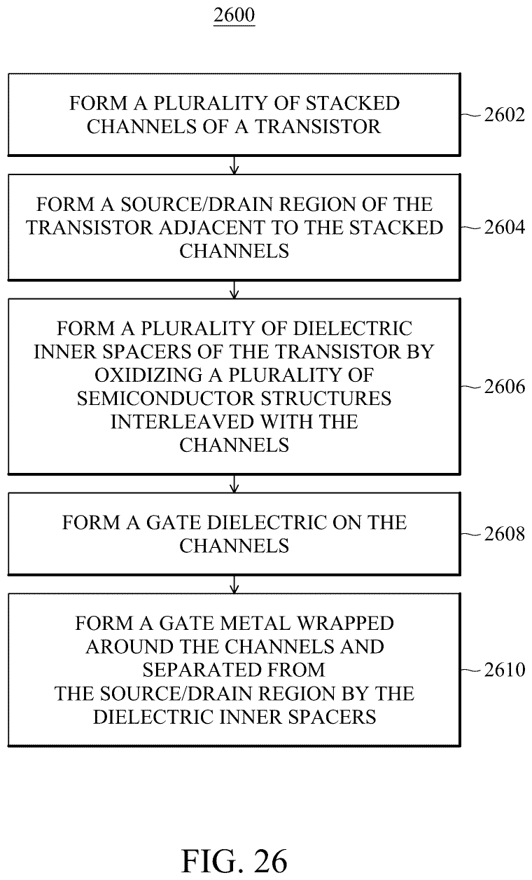

FIG. 26 is a flow diagram of a method 2600 for forming an integrated circuit, in accordance with some embodiments. The method 2600 can utilize the structures, processes, and systems described in relation to FIGS. 1-24. At 2602, the method 2600 includes forming a plurality of stacked channels of a transistor. One example of a transistor is the transistor 101 of FIG. 19B. One example of stacked channels are the stacked channels 105 of FIG. 19B. At 2604, the method 2600 includes forming a source/drain region of the transistor adjacent to the stacked channels. One example of a source/drain region is the source/drain region 140 of FIG. 19B. At 2606, the method 2600 includes forming a plurality of dielectric inner spacers of the transistor by oxidizing a plurality of semiconductor structures interleaved with the channels. One example of semiconductor structures are the semiconductor structures 137 of FIG. 17B. One example of dielectric inner spacers are the dielectric inner spacers 136 of FIG. 19B. At 2608, the method 2600 includes forming a gate dielectric on the channels. One example of a gate dielectric is the gate dielectric 164 of FIG. 19B. At 2610, the method 2600 includes forming a gate metal wrapped around the channels and separated from the source/drain region by the dielectric inner spacers. One example of a gate metal is the gate metal 166 of FIG. 19B.

Embodiments of the disclosure provide a gate all around transistor including first and second source/drain regions, a plurality of stacked channels each extending between the first and second source/drain regions, a gate metal wrapped around the channels, and low K inner spacers positioned between adjacent channels and electrically isolating the gate metal from the source/drain regions. Embodiments of the present disclosure advantageously form the inner spacers after formation of the source/drain regions. More particularly, embodiments of the present disclosure form dielectric nanostructures between the channels, recess the dielectric nanostructures, form semiconductor structures in the recesses, and form a semiconductor seed layer on the ends of the channels and on the outside surfaces of the semiconductor structures. The source/drain regions are grown epitaxially from the semiconductor seed layer and the dielectric nanostructures are removed. After removal of the dielectric nanostructures, low K dielectric inner spacers are formed in place of the sacrificial semiconductor nanostructures. The dielectric inner spacers can include an oxide or an air gap. The gate metal is then formed. The result is reduced capacitance between the gate metal and source/drain regions, increased switching speeds of the transistor, higher-quality source/drain regions, enhanced strain for improved device performance, and reduced time in forming the source/drain regions.

In some embodiments, a method includes forming a plurality of stacked channels of a transistor, forming a semiconductor seed layer on ends of the stacked channels, and forming a source/drain region of the transistor by performing an epitaxial growth from the seed layer. The method includes after forming the source/drain region, forming a plurality of dielectric inner spacers interleaved with the channels and separated from the source/drain region by the semiconductor seed layer and forming a gate metal of the transistor wrapped around the channels and separated from the source/drain region by the dielectric inner spacers.

In some embodiments, an integrated circuit includes a transistor. The transistor includes a plurality of stacked channels, a gate metal wrapped around the channels, and a gate dielectric between the channels and the gate metal. The transistor includes a plurality of dielectric inner spacers interleaved with the channels, a source/drain region, and a semiconductor seed layer positioned between the inner spacers and the source/drain region.

In some embodiments, a method includes forming a plurality of stacked channels of a transistor, forming a source/drain region of the transistor adjacent to the stacked channels, and forming a plurality of dielectric inner spacers of the transistor by oxidizing a plurality of semiconductor structures interleaved with the channels. The method includes forming a gate dielectric on the channels and forming a gate metal wrapped around the channels and separated from the source/drain region by the dielectric inner spacers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a plurality of stacked channels;
forming a semiconductor seed layer on ends of the stacked channels;
forming a source/drain region of the transistor by performing an epitaxial growth from the seed layer;
after forming the source/drain region, forming a plurality of dielectric inner spacers interleaved with the channels and separated from the source/drain region by the semiconductor seed layer; and
forming a gate metal of the transistor wrapped around the channels and separated from the source/drain region by the dielectric inner spacers.

2. The method of claim 1, wherein the dielectric inner spacers are gaps filled with fluid.

3. The method of claim 1, comprising:
forming semiconductor structures interleaved with the channels; and
forming the semiconductor seed layer with an epitaxial growth from ends of the stacked channels and from ends of the semiconductor structures.

4. The method of claim 3, comprising forming the dielectric inner spacers in place of the semiconductor structures.

5. The method of claim 4, wherein forming the dielectric inner spacers includes converting the semiconductor structures to dielectric inner spacers by oxidizing the semiconductor structures.

6. The method of claim 5, wherein forming the dielectric inner spacers includes:
generating a plasma in a presence of the semiconductor structures; and
oxidizing the semiconductor structures.

7. The method of claim 5, wherein forming the dielectric inner spacers includes:
forming a plurality of porous dielectric membranes interleaved with the channels; and
removing the semiconductor structures via the porous dielectric membranes, wherein the dielectric inner spacers are gaps filled with a fluid; and
forming the gate metal adjacent to the porous dielectric membranes.

8. The method of claim 7, comprising:
forming a gate dielectric layer in contact with the porous dielectric membranes; and
forming the gate metal in contact with the gate dielectric layer and separated from the porous dielectric membranes by the gate dielectric layer.

9. The method of claim 3, comprising:
forming dielectric nanostructures interleaved with the channels;
forming recesses by recessing end portions of the dielectric nanostructures;
forming the semiconductor structures in the recesses after recessing the end portions of the dielectric nanostructures; and
removing the dielectric nanostructures after forming the semiconductor structures.

10. The method of claim 1, wherein the dielectric inner spacers include silicon oxide or silicon germanium oxide.

11. An integrated circuit, comprising:
a transistor including:
a plurality of stacked channels;
a gate metal wrapped around the channels;
a gate dielectric between the channels and the gate metal;
a plurality of dielectric inner spacers interleaved with the channels;
a source/drain region; and
a semiconductor seed layer positioned between the inner spacers and the source/drain region.

12. The integrated circuit of claim 11, wherein the dielectric inner spacers include silicon oxide or silicon germanium oxide.

13. The integrated circuit of claim 11, wherein outer ends of the channels are laterally offset with respect to the inner spacers.

14. The integrated circuit of claim 13, wherein the semiconductor seed layer include a plurality of seams filled with the source/drain region.

15. The integrated circuit of claim 11, wherein the transistor includes a plurality of porous dielectric membranes interleaved with the channels and each positioned between the gate metal and a respective inner spacer.

16. The integrated circuit of claim 15, wherein the gate dielectric is in contact with the porous dielectric membranes.

17. The integrated circuit of claim 11, wherein the dielectric inner pacers are gaps filled with fluid.

18. A method, comprising:
forming a plurality of stacked channels;
forming a source/drain region adjacent to the stacked channels;
forming a plurality of dielectric inner spacers of the transistor by oxidizing a plurality of semiconductor structures interleaved with the channels;
forming a gate dielectric on the channels; and
forming a gate metal wrapped around the channels and separated from the source/drain region by the dielectric inner spacers.

19. The method of claim 18, wherein forming the dielectric inner spacers includes:
generating, from each semiconductor structure, a porous dielectric membrane by oxidizing an inner end of the of the semiconductor structure; and
removing a remaining portion of each semiconductor structure via the porous dielectric membrane, wherein after forming the gate metal, each porous dielectric membrane is positioned between the gate metal and the source/drain region.

20. The method of claim 18, wherein forming the dielectric inner spacers includes converting each semiconductor structure into a respective dielectric inner spacer of the plurality of dielectric inner spacers by oxidizing the semiconductor structures.
